(19) United States
(12) Patent Application Publication
(10) Pub. No.: US 2007/0241823 A1
(43) Pub. Date: Oct. 18, 2007

(54) RAIL-TO-RAIL INPUT VOLTAGE-CONTROLLED OSCILLATING DEVICE

(76) Inventors: Chao-Cheng Lee, Hsin-Chu City (TW); Tzu-Chien Tzeng, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/689,517

(22) Filed: Mar. 22, 2007

(30) Foreign Application Priority Data
Apr. 3, 2006 (TW) 095111837

(51) Int. Cl. H03L 7/00

(52) U.S. Cl. 331/16

(57) ABSTRACT

The present invention discloses a voltage-controlled oscillating apparatus to generate an oscillating signal. The voltage-controlled oscillating device includes: a regulating circuit, a biasing circuit, and an oscillator. In which the regulating circuit includes an amplifier, with a first input terminal coupled to a control voltage; and a voltage adjusting circuit, coupled between a second input terminal and an output terminal to feed a feedback voltage back to the second input terminal of the amplifier, and adjust the feedback voltage according to the output signal in the output terminal of the amplifier. The biasing circuit is coupled to the output terminal of the amplifier to generate a biasing signal according to the output signal in the output terminal of the amplifier; and the oscillator is coupled to the biasing circuit to generate the oscillating signal according to the biasing signal.

### BACKGROUND OF THE INVENTION

1. Field of the Invention

The present invention is related to a voltage-controlled oscillating device, and more particularly, to a low voltage and full input swing voltage-controlled oscillating device.

2. Description of the Prior Art

With advanced semiconductor manufacturing processes, chip devices are becoming more compact. As a result of the smaller design, the operating voltage of the semiconductor chip has been reduced as well. Thereby, the input voltage range of a prior art voltage controlled oscillator can also be limited to a smaller range. If the range of an output frequency is invariant, then by reducing the input voltage range the gain of the voltage controlled oscillator will increase. However, in the prior art, a nonlinear characteristic transfer function between the control voltage and the oscillating frequency of the voltage controlled oscillator will emerge when reducing the supply voltage of the voltage controlled oscillator if the range of the oscillating frequency and the gain of the voltage controlled oscillator are invariant. Please refer to the related art as cited hereinafter for addition details that omitted herein for the sake of brevity:

[1] John G. Maneatis, “Low-jitter Process Independent DLL and PLL Based on Self-Biased Techniques,” IEEE JSSC, vol. 31, pp. 1723-1731, November 1996.

[2] Ron Hogervorst, John P. Tero, and Johan H. Huijsing, “Compact CMOS Constant-gm Rail-to-Rail Input Stage with gm-control by an Electronic Zener Diode,” IEEE JSSC, vol. 31, pp. 1035-1040, July, 1996.

[3] Kun-Yung Ken Chang, Jason Wei, Charlie Huang, Simon Li, Kevin Donnelly, Mark Horowitz, Yingxuan Li, and Stefanos Sidiropoulos, “A 0.4-4 Gb/s CMOS Quad Transceiver Cell using On-chip Regulated Dual-loop PLLs,” IEEE JSSC, vol. 38, pp. 747-754, May, 2003.

[4] Howard C. Yand, Lance K. Lee, and Ramon S. Co “A Low Jitter 0.3-165 MHz CMOS PLL Frequency Synthesizer for 3V/5V Operation,” IEEE JSSC, vol. 32, pp. 582-586, April, 1997.

Reference [1] illustrates a voltage-controlled oscillator with self-biased technique for lowing the jittering effect. Reference [2] illustrates a prior art rail-to-rail output transconductance amplifier. Reference [3] illustrates a PLL with linear regulator for lowing the jittering effect. Reference [4] illustrates a PLL with single-ended current-steering amplifier for lowing the jittering effect.

It is apparent based on the prior art that new and innovative techniques and devices are needed.

### SUMMARY OF THE INVENTION

Therefore, it is an objective of the present invention is to provide a low voltage and full input swing voltage-controlled oscillating device to solve the above-mentioned problems.

According to an embodiment of the present invention, a voltage-controlled oscillating device is disclosed. The voltage-controlled oscillating device, for generating an oscillating signal, includes: a regulating circuit having: an amplifier with a first input terminal coupled to a control voltage and a voltage adjusting circuit, coupled between a second input terminal and an output terminal to feed a feedback voltage back to the second input terminal of the amplifier, and adjust the feedback voltage according to the output signal in the output terminal of the amplifier; a biasing circuit, coupled to the output terminal of the amplifier to generate a biasing signal according to the output signal in the output terminal of the amplifier; and an oscillator, coupled to the biasing circuit, to generate the oscillating signal according to the biasing signal.

According to an embodiment of the present invention, a voltage-controlled oscillating device is disclosed. The voltage-controlled oscillating device is for generating an oscillating signal, and includes: a biasing circuit, for generating a biasing signal according to a control voltage; and an oscillator, coupled to the biasing circuit. The oscillator comprises: a latch device, with a first input terminal, a second input terminal, a first output terminal, and a second output terminal, where the second output terminal is utilized for outputting the oscillating signal; and a single-to-differential device, for converting the output signal in the first output terminal of the latch device into a first differential output signal and a second differential signal according to the biasing signal. The single-to-differential device includes an input terminal, coupled to the first output terminal of the latch device; a first differential output terminal, coupled to the first input terminal of the latch device, for outputting the first differential output signal; and a second differential output terminal, coupled to the second input terminal of the latch device, for outputting the second differential output signal.

According to an embodiment of the present invention, a voltage-controlled oscillating device is disclosed. The voltage-controlled oscillating device includes: a voltage-to-current converter, for converting a control voltage into an output current; a current generating device, for generating a control current according to the control voltage, wherein the control current varies in response to the output current; and an oscillator, for generating an oscillating signal according to the control current.

According to an embodiment of the present invention, a phase lock loop apparatus is disclosed. The phase lock loop apparatus includes: a phase/frequency detector, for generating an adjusting signal according to frequency of a reference signal and frequency of an oscillating signal; a charge pump, for generating a control signal according to the adjusting signal; a voltage-controlled oscillating device, for generating the oscillating signal according to the control signal; and a feedback path, for feeding the oscillating signal back to the phase/frequency detector. The voltage-controlled oscillating device includes: a voltage-to-current converter, for converting a control voltage into an output current; a current generating device, for generating a control current according to the control voltage, wherein the control current varies in response to the output current; and an oscillator, for generating the oscillating signal according to the control current;

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a voltage-controlled oscillating device according to an embodiment of the present invention.

FIG. 2 is a timing diagram illustrating the operation of generating the oscillating signal of the voltage-controlled oscillating device in FIG. 1.

FIG. 3 is a diagram illustrating a phase lock loop that utilizing voltage-controlled oscillating device in FIG. 1.

### DETAILED DESCRIPTION

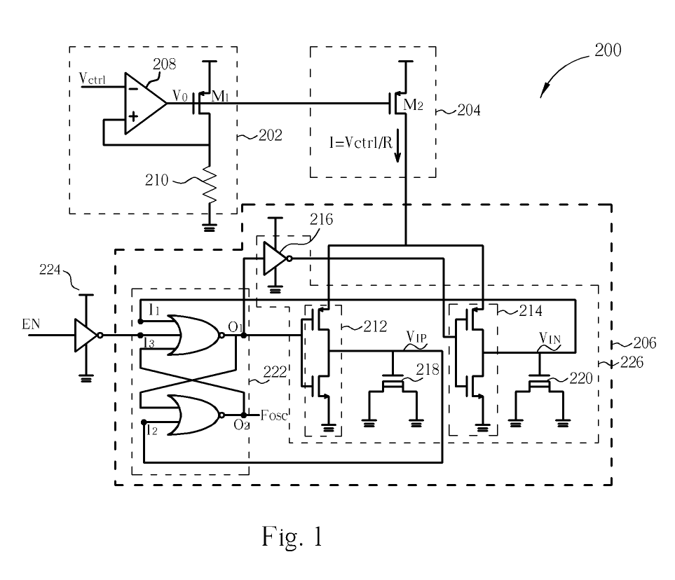

Please refer to FIG. 1. FIG. 1 illustrates a voltage-controlled oscillating device 200 according to an embodiment of the present invention. The voltage-controlled oscillating device 200 comprises a regulating circuit 202, a biasing circuit 204, and an oscillator 206. When the voltage-controlled oscillating device 200 operates in a low supply voltage device and outputs an oscillating signal, the regulating circuit 202 provides a full range input control signal and generates a regulated voltage signal to voltage-controlled oscillating device 200 linearly. The biasing circuit 204 converts the regulated voltage signal into a current biased signal of the oscillator 206 to provide the power of the oscillator 206. Then, the oscillator 206 adjusts an oscillating frequency of an output oscillating signal Fosc according to the current biased signal that is provided by the biasing circuit 204. In this embodiment, the oscillator 206 is a current controlled oscillator (CCO).

In this embodiment, the biasing circuit 204 comprises a full range input amplifier 208. A prior art full range input amplifier 208 is a rail-to-rail output transconductance amplifier (rail-to-rail OTA), a first input terminal of the full range input amplifier 208 is coupled to a control voltage Vctrl, wherein the control voltage Vctrl has a full range input in order to provide a wider control range when operating in a low voltage supply apparatus (e.g., 0V to Vdd). Furthermore, the biasing circuit 204 further comprises a voltage adjusting circuit that comprises a plurality of P-type transistor M1, M2 and a resistor 210. The gate terminal of the P-type transistor M1 is coupled to the output terminal of the full range input amplifier 208, the drain terminal of the P-type transistor M1 is coupled to the second input terminal of the full range input amplifier 208, and the transistor 210 is coupled to the source terminal of the P-type transistor M1. Therefore, the voltage adjusting circuit is utilized to feedback a feedback voltage into the second input terminal of the full range input amplifier 208, and to adjust the feedback voltage according to an output signal at the output terminal of the full range input amplifier 208. Moreover, because the first input terminal and the second input terminal are coupled to the negative input terminal and the positive terminal of the full range input amplifier 208, respectively, therefore when the control voltage Vctrl increases, the voltage over transistor 210 also increases. Meanwhile, the voltage at the output terminal of the full range input amplifier 208 is decreased to turn on the P-type transistor M1 to provide the current that flows through the resistor 210. Accordingly, the current flow through the resistor 210 and the control voltage Vctrl have a linear relationship. In other words, if the resistance of the resistor 210 is R, then the current that flows through the resistor 210 is Vctrl/R. On the other hand, the P-type transistor M2 is utilized as a biasing circuit, the gate terminal coupled to the output terminal of the full range input amplifier 208, and the drain terminal coupled to the oscillator 206 to provide a current biasing signal I that required by the oscillator 206. The current biasing signal I that is generated by the biasing circuit (i.e., P-type transistor M2) is K*Vctrl/R because the size of the P-type transistor M2 is k times that of the P-type transistor M1, and because both consist of the same biasing condition. Accordingly, an output frequency and the input signal also have a linear relationship. Please note that, in this embodiment of the present invention, k=1.

The oscillator 206 is coupled to the biasing circuit 204 for generating a current biasing signal I according to the oscillating signal Fosc. In this embodiment of the present invention, the oscillator 206 comprises a latch circuit 222 and a single-to-differential circuit 226. The latch circuit 222 comprises two NOR gates, which include a first input terminal I₁, a second input terminal I₂, a first output terminal O₁, and a second output terminal O₂, wherein the second output terminal O₂ is utilized to output the oscillating signal Fosc; the single-to-differential circuit 226 is utilized to convert the output signal at the first output terminal O₁ of the latch circuit 222 into a first differential output signal V1p, and a second differential output signal V1n according to the current biasing signal I; and the first and the second differential output signals V1p, V1n are then feedback to the second input terminal I₂ and the first input terminal I₁.

Please refer to FIG. 1. FIG. 1 illustrates a single-to-differential circuit 226. The single-to-differential circuit 226 comprises a first transistor capacitor 218, in which the gate terminal is coupled to the output of a first inverter 212, and the drain and the source terminals are coupled to a ground; a second transistor capacitor 220, in which the gate terminal is coupled to the output of a second inverter 214; the first inverter 212 is coupled to the first output terminal O₁ of the latch circuit 222, the first transistor capacitor 218, and the biasing circuit 204; the second inverter 214 is coupled to the second transistor capacitor 220, and the biasing circuit 204; a third inverter 216 is coupled between the first output terminal O₁ and the second inverter 214. Accordingly, the configuration is capable of preventing the circuit from oscillating when in a common mode. Furthermore, the chip area will increase in size substantially if utilizing the analog semiconductor processing to implement a capacitor, but the chip area will decrease substantially in size if utilizing the N-type transistor capacitor to implement the capacitor. However, the capacitance will decrease tremendously right before enter to strong inversion (e.g., both Vgs and Vgd smaller that Vtn) mode whenever the N-type transistor capacitor is utilized, thus the nonlinear characteristic of the N-type transistor capacitor will affect the voltage-controlled oscillating device 200 to perform a nonlinear transform function of the control voltage that is below Vtn. Accordingly, this embodiment of the present invention utilizes a Native NMOS to implement the transistor capacitor of the voltage-controlled oscillating device 200. The Native NMOS can be implemented under the CMOS process, and without an extra optical mask and manufacturing step. Moreover, this embodiment of the present invention also can utilize a depleted NMOS to implement the transistor capacitor of the voltage-controlled oscillating device 200. The depleted NMOS is an NMOS that is implemented within a N-well, thus the equivalent Vth is approximated to (or smaller than) 0V. When the Native NMOS is utilized, the supply voltage will not affect the characteristic of the capacitor, and the capacitance will be almost fixed. Furthermore, the chip area that is utilized by the Native NMOS is as small as the chip area that is utilized by the depleted NMOS.

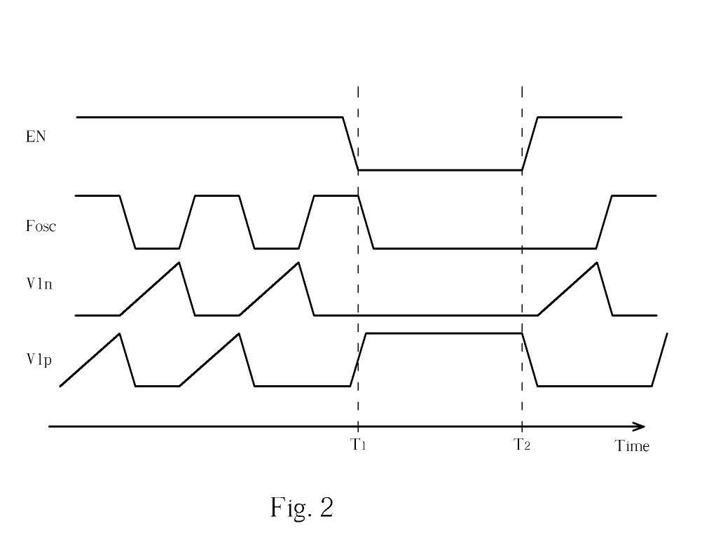

Accordingly, when the current biasing signal I is generated, if the output signal of the first output terminal O₁ of the latch circuit 222 is a high level signal, the high level signal will pass through the first inverter 212 to discharge the first transistor capacitor 218; at the same time, the high level signal will pass through the second inverter 214 and the third inverter 216 to charge the second transistor capacitor 220. The lowering time of the voltage level at the second input terminal I₂ is faster that the rising time of the voltage level at the first input terminal I₁ that will consequently result the second output terminal O₂ of the latch circuit 222 be lowered into a low level voltage because the discharging time of the present embodiment is designed to be far smaller that the charging time. After discharging for a while, when the voltage of the first input terminal I₁ is rising to a high level voltage, the voltage of the first output terminal O₁ of the latch circuit 222 will then be lowered into the low level voltage. Then, the single-to-differential circuit 226 executes a reversed charging and discharging operation; accordingly, the second output terminal O₂ of the latch circuit 222 is generating an oscillating signal Fosc. Furthermore, when the capacitance of the first transistor capacitor 218 is equal to the capacitance of the second transistor capacitor 220, then the charging current is fixed at Vctrl/R. Accordingly, the charging time is also fixed and not varying with time and supply voltage. However, the discharging current is not limited, if the discharging current is designed to be much larger that the charging current, then the duty cycle of the oscillating signal Fosc will be approximated 50% according to the charging and discharging operation between the first and the second inverter 212, 214 as shown in FIG. 1. The operation of the generating oscillating signal Fosc by the oscillator 206 is shown in FIG. 2.

Furthermore, a third input terminal I₃ can be coupled to the latch circuit 222 for receiving an enable signal EN; the third input terminal I₃ is capable of instantly deactivating/activating the latch circuit 222 for controlling the output of the oscillating signal Fosc. When the enable signal EN is at a high level, the oscillator 206 outputs the oscillating signal Fosc, otherwise the oscillator 206 does not output the oscillating signal Fosc. Please refer to FIG. 1. In FIG. 1, the enable signal EN is first transmitted to an inverter 224, then coupled to an input terminal of a NOR gate; thus in this way to control the NOR gate is also capable of controlling the operation of the voltage-controlled oscillating device 200. The related timing diagram is shown in FIG. 2. In FIG. 2, the enable signal EN is at a low voltage level in T₁ through T₂, thus in the time interval between T₁ and T₂, the first differential output signal V1p and the second differential output signal V1n will sustain the voltage level of time T₁ and not vary to the other voltage level. In other words, the oscillator 206 will not generate the oscillating signal. Please note that, the above mentioned deactivate/activate latch circuit 222 is not provided as a limitation to the configuration that is shown in FIG. 1 but only by way of example. Furthermore, to couple the enable signal EN to another NOR gate of latch circuit 222 is also included in the spirit of the present invention, and the latch circuit 222 can be implemented by two NAND gates or by two NOR gates. Accordingly, the voltage-controlled oscillating device 200 with the enable signal EN is capable of performing a clock and data recovery phase lock loop (CDR PLL).

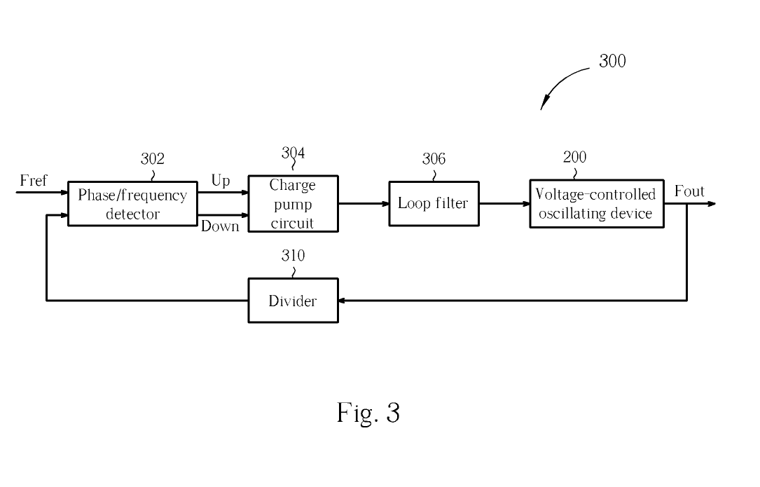

Please refer to FIG. 3. FIG. 3 illustrates a diagram of embodiment of a phase lock loop 300 utilizing the voltage-controlled oscillating device 200 of the present invention. The phase lock loop 300 comprises a phase/frequency detector 302 for generating a group of adjusting signals UP, Down according to the frequency of a reference signal Fref and the frequency of a oscillating signal Fout; a charge pump circuit 304 for generating a control signal according to adjusting signals UP, Down; a loop filter 306 for performing a filtering of the control signal; voltage-controlled oscillating device 200 for generating oscillating signal Fout according to the filtered control signal. The voltage-controlled oscillating device 200 comprises a regulating circuit 202 for converting the control signal Vctrl into an output voltage Vo; a biasing circuit 204 for generating a control current I according to the output voltage Vo, wherein the control current I varies linearly according to the output voltage Vo; and an oscillator 206 for generating the oscillating signal Fout according to the control current I; and a divider 310 for dividing the frequency of the oscillating signal and feeding back the frequency of the oscillating signal as a feedback to a phase/frequency detector 302. Additionally, the regulating circuit 202 comprises a full range input amplifier 208 for generating the output voltage Vo according to the control signal Vctrl; and a feedback circuit comprises a transistor M1 coupled to an output terminal of the full range input amplifier 208 for determining the output voltage Vo. The oscillator 206 comprises a single-to-differential circuit 226 for generating a differential signal according to the control current I; and latch circuit 222 for generating the oscillating signal Fout according to the differential signal. Finally, the oscillating signal Fout is passed through a divider 310 to feedback into a phase/frequency detector 302 for performing a phase locking operation. Because the voltage-controlled oscillating device 200 of the phase lock loop 300 is an embodiment of the present invention, the detailed circuit and operation was described above, thus further description is omitted in this embodiment. Furthermore, the locking operation of the phase lock loop 300 are well known by those having average skill in this art, therefore the well known details are omitted in this embodiment for the sake of brevity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A voltage-controlled oscillating device, for generating an oscillating signal, the voltage-controlled oscillating device comprising:
a regulating circuit, comprising:
an amplifier, with a first input terminal coupled to a control voltage; and
a voltage adjusting circuit, coupled between a second input terminal and an output terminal of the amplifier, operative to feed a feedback voltage back to the second input terminal of the amplifier, and adjust the feedback voltage according to an output signal in the output terminal of the amplifier;
a biasing circuit, coupled to the output terminal of the amplifier to generate a biasing signal according to the output signal in the output terminal of the amplifier; and
an oscillator, coupled to the biasing circuit, operative to generate the oscillating signal according to the biasing signal.

2. The voltage-controlled oscillating device of claim 1, wherein the amplifier is a rail-to-rail output transconductance amplifier.

3. The voltage-controlled oscillating device of claim 1, wherein the amplifier is a full input swing amplifier.

4. The voltage-controlled oscillating device of claim 1, wherein the voltage adjusting circuit comprises:
a transistor, with a gate terminal coupled to the output terminal of the amplifier, a drain terminal coupled to the second input terminal of the amplifier; and
a resistance device, coupled to the drain terminal of the transistor.

5. The voltage-controlled oscillating device of claim 1, wherein the biasing circuit comprises a transistor having a gate terminal coupled to the output terminal of the amplifier and a drain terminal coupled to the oscillator to provide the biasing signal.

6. The voltage-controlled oscillating device of claim 1, wherein the oscillator comprises:
a latch device, with a first input terminal, a second input terminal, a first output terminal, and a second output terminal, wherein the second output terminal is utilized for outputting the oscillating signal; and
a single-to-differential device, for converting an output signal in the first output terminal of the latch device into a first differential output signal and a second differential signal according to the biasing signal, wherein the single-to-differential device comprises an input terminal coupled to the first output terminal of the latch device; a first differential output terminal, coupled to the first input terminal of the latch device, for outputting the first differential output signal; and a second differential output terminal, coupled to the second input terminal of the latch device, for outputting the second differential output signal.

7. The voltage-controlled oscillating device of claim 6, wherein the single-to-differential device comprises:
a first capacitor, with a terminal coupled to the first differential output terminal of the single-to-differential device;
a second capacitor, with a terminal coupled to the second differential output terminal of the single-to-differential device;
a first switching device, coupled to the first output terminal of the latch device, the first capacitor, and the biasing circuit, for selectively controlling the biasing signal to charge the first capacitor or to discharge the first capacitor according to the output signal of the first output terminal of the latch device; and
a second switching device, coupled to the second capacitor and the biasing circuit, for selectively controlling the biasing signal to charge the second capacitor or to discharge the second capacitor according to the output signal of the first output terminal of the latch device;
wherein if the first switching device controls the biasing signal to charge the first capacitor, then the second switching device controls the second capacitor to discharge; and if the second switching device controls the biasing signal to charge the second capacitor, then the first switching device controls the first capacitor to discharge.

8. The voltage-controlled oscillating device of claim 6, wherein the latch device further comprises a third input terminal, for receiving an enable signal to control if the latch device is activated.

9. A voltage-controlled oscillating device, for generating an oscillating signal, the voltage-controlled oscillating device comprising:
a biasing circuit, for generating a biasing signal according to a control voltage; and
an oscillator, coupled to the biasing circuit, the oscillator comprising:
a latch device, with a first input terminal, a second input terminal, a first output terminal, and a second output terminal, wherein the second output terminal is utilized for outputting the oscillating signal; and
a single-to-differential device, for converting the output signal in the first output terminal of the latch device into a first differential output signal and a second differential signal according to the biasing signal, wherein the single-to-differential device comprises an input terminal coupled to the first output terminal of the latch device; a first differential output terminal, coupled to the first input terminal of the latch device, for outputting the first differential output signal; and a second differential output terminal, coupled to the second input terminal of the latch device, for outputting the second differential output signal.

10. The voltage-controlled oscillating device of claim 9, wherein the single-to-differential device comprises:
a first capacitor, with a terminal coupled to the first differential output terminal of the single-to-differential device;
a second capacitor, with a terminal coupled to the second differential output terminal of the single-to-differential device;
a first switching device, coupled to the first output terminal of the latch device, the first capacitor, and the biasing circuit, for selectively controlling the biasing signal to charge the first capacitor or to discharge the first capacitor according to the output signal of the first output terminal of the latch device; and
a second switching device, coupled to the second capacitor and the biasing circuit, for selectively controlling the biasing signal to charge the second capacitor or to discharge the second capacitor according to the output signal of the first output terminal of the latch device;
wherein if the first switching device controls the biasing signal to charge the first capacitor, then the second switching device controls the second capacitor to discharge; and if the second switching device controls the biasing signal to charge the second capacitor, then the first switching device controls the first capacitor to discharge.

11. The voltage-controlled oscillating device of claim 9, wherein the latch device further comprises a third input terminal, for receiving an enable signal to control if the latch device is activated.

12. A voltage-controlled oscillating device, comprising:
a voltage-to-current converter, for converting a control voltage into a output current;
a current generating device, for generating a control current according to the control voltage, wherein the control current varies in response to the output current; and
an oscillator, for generating an oscillating signal according to the control current.

13. The voltage-controlled oscillating device of claim 12, wherein the voltage-to-current converter comprises:
an amplifier, for generating an output voltage according to the control voltage; and
a feedback circuit, for generating the output current, and feeding a feedback voltage back to an input terminal of the amplifier;
wherein amplitude of the feedback voltage is larger than amplitude of the output voltage.

14. The voltage-controlled oscillating device of claim 13, wherein the amplifier is a rail-to-rail output transconductance amplifier.

15. The voltage-controlled oscillating device of claim 13, wherein the amplifier is a full input swing amplifier.

16. The voltage-controlled oscillating device of claim 13, wherein the feedback circuit comprises:
a first transistor, coupled to an output terminal of the amplifier, for generating the feedback voltage; and
a resistance device, coupled to the first transistor and the input terminal of the amplifier, for determining the output current.

17. The voltage-controlled oscillating device of claim 16, wherein the feedback circuit is coupled to the current generating device by utilizing a current mirror configuration.

18. The voltage-controlled oscillating device of claim 12, wherein the oscillator is a current-controlled oscillator or a voltage-controlled oscillator.

19. The voltage-controlled oscillating device of claim 18, wherein the oscillator comprises:
a single-to-different circuit, for generating a differential signal according to the control current; and
a latch device, for generating the oscillating signal according to the differential signal.

20. The voltage-controlled oscillating device of claim 12, wherein the voltage-to-current converter is coupled to the current generating device by utilizing a current mirror configuration.

21. A phase lock loop apparatus, comprising:
a phase/frequency detector, for generating an adjusting signal according to frequency of a reference signal and frequency of an oscillating signal;
a charge pump, for generating a control signal according to the adjusting signal;
an voltage-controlled oscillating device, for generating the oscillating signal according to the control signal, the voltage-controlled oscillating device comprising:
a voltage-to-current converter, for converting a control voltage into an output current;
a current generating device, for generating a control current according to the control voltage, wherein the control current varies in response to the output current; and
an oscillator, for generating the oscillating signal according to the control current;
a feedback path, for feeding the oscillating signal back to the phase/frequency detector.

22. The phase lock loop apparatus of claim 21, wherein the voltage-to-current converter comprises:
an amplifier, for generating an output voltage according to the control voltage; and
a feedback circuit, for generating the output current, and feeding a feedback voltage back to an input terminal of the amplifier;
wherein amplitude of the feedback voltage is larger than amplitude of the output voltage.

23. The phase lock loop apparatus of claim 22, wherein the amplifier is a rail-to-rail output transconductance amplifier.

24. The phase lock loop apparatus of claim 22, wherein the amplifier is a full input swing amplifier.

25. The phase lock loop apparatus of claim 22, wherein the feedback circuit comprises:
a first transistor, coupled to output terminal of the amplifier, for generating the feedback voltage; and
a resistance device, coupled to the first transistor and the input terminal of the amplifier, for determining the output current.

26. The phase lock loop apparatus of claim 25, wherein the feedback circuit is coupled to the current generating device by utilizing a current mirror configuration.

27. The phase lock loop apparatus of claim 21, wherein the oscillator is a current-controlled oscillator or a voltage-controlled oscillator.

28. The phase lock loop apparatus of claim 27, wherein the oscillator comprises:
a single-to-different circuit, for generating a differential signal according to the control current; and
a latch device, for generating the oscillating signal according to the differential signal.

29. The phase lock loop apparatus of claim 21, wherein the voltage-to-current converter is coupled to the current generating device by utilizing a current mirror configuration.
